(19) United States
(12) Patent Application Publication
(10) Pub. No.: US 2026/0223509 A1
(43) Pub. Date: Jul. 30, 2026

(54) DISPLAY DEVICE AND MANUFACTURING METHOD THEREOF

(71) Applicant: Ennostar Corporation, Hsinchu City (TW)

(72) Inventors: Zhen-Kai KAO, Hsinchu City (TW); Hsia-Ching CHENG, Hsinchu City (TW); Yu-Chi WANG, Hsinchu City (TW); Kun-Lin LI, Hsinchu City (TW); Hui-Ching FENG, Hsinchu City (TW); Yih-Hua RENN, Hsinchu City (TW)

(21) Appl. No.: 19/454,076

(22) Filed: Jan. 20, 2026

(30) Foreign Application Priority Data
Jan. 24, 2025 (TW) 114103307

(51) Int. Cl. H10H 29/80; H10H 29/01; H10H 29/14; H10H 29/851; H10H 29/853

(52) U.S. Cl. CPC H10H 29/8321; H10H 29/032; H10H 29/0361; H10H 29/0362; H10H 29/14; H10H 29/8513; H10H 29/853

(57) ABSTRACT

A display device includes a wavelength-conversion module and a light-emitting module. The wavelength-conversion module includes a first wavelength-conversion layer, a second wavelength-conversion layer, and a conductive structure. The first wavelength-conversion layer has a first lower surface. The conductive structure has a first portion and a second portion which are connected to each other, and the first portion is disposed between the first wavelength-conversion layer and the second wavelength-conversion layer. The first portion has a second lower surface coplanar with the first lower surface. The light-emitting module is disposed over the wavelength-conversion module and exposes the second portion. The light-emitting module includes a first semiconductor layer, a first light-emitting layer, and a second light-emitting layer. The first light-emitting layer and the second light-emitting layer are disposed on the first semiconductor layer, the first light-emitting layer covers the first wavelength-conversion layer, and the second light-emitting layer covers the second wavelength-conversion layer.

### CROSS-REFERENCE TO RELATED APPLICATIONS

This application claims priority to, and the benefit of, Taiwan Patent Application Number 114103307 filed on January 24, 2025, the entirety of which is hereby incorporated by reference.

### TECHNICAL FIELD

The present disclosure relates to a display device, and more particularly, to a display device including a wavelength-conversion module and a light-emitting module, and to a manufacturing method thereof.

### BACKGROUND

With the widespread application of display devices in various electronic products, performance requirements continue to increase. In display devices, multiple semiconductor stacks are typically formed on a substrate, and electrodes are disposed on the stacks to enable light emission by applying a voltage to the electrodes. However, the height differences of these electrodes complicate subsequent manufacturing processes and reduce overall product yield. Furthermore, if the area occupied by the electrodes is too large, it may result in insufficient overall light-emitting area of the display device. Accordingly, although the display devices and their manufacturing methods have advanced toward their intended applications, certain shortcomings remain. There are still problems to be solved regarding the display devices and their manufacturing methods.

### SUMMARY

In one embodiment, a display device is provided. The display device includes a wavelength-conversion module and a light-emitting module. The wavelength-conversion module includes a first wavelength-conversion layer, a second wavelength-conversion layer, and a conductive structure. The first wavelength-conversion layer has a first lower surface. The conductive structure has a first portion and a second portion which are connected to each other, and the first portion is disposed between the first wavelength-conversion layer and the second wavelength-conversion layer. The first portion has a second lower surface that is coplanar with the first lower surface. The light-emitting module is disposed over the wavelength-conversion module, with the second portion exposed. The light-emitting module includes a first semiconductor layer, a first light-emitting layer, and a second light-emitting layer. The first light-emitting layer and the second light-emitting layer are disposed on the first semiconductor layer, the first light-emitting layer covers the first wavelength-conversion layer, and the second light-emitting layer covers the second wavelength-conversion layer.

In one embodiment, a method for manufacturing a display device is provided. The method includes forming a wavelength-conversion module that includes a first wavelength-conversion layer, a second wavelength-conversion layer, a conductive structure, and an encapsulation layer. The first wavelength-conversion layer and the second wavelength-conversion layer are arranged side by side, and the first wavelength-conversion layer has a first lower surface. The conductive structure has a first portion and a second portion that are connected to each other, and the first portion is disposed between the first wavelength-conversion layer and the second wavelength-conversion layer. The first portion has a second lower surface, and the first lower surface and the second lower surface are coplanar with each other. The encapsulation layer covers the first portion, the first wavelength-conversion layer, and the second wavelength-conversion layer. The method further includes forming a light-emitting module that includes a first semiconductor layer, a first light-emitting layer, a second light-emitting layer, and a plurality of second semiconductor layers. The first light-emitting layer and the second light-emitting layer are disposed on the first semiconductor layer. The plurality of second semiconductor layers is disposed on the first and second light-emitting layers. The method further includes combining the wavelength-conversion module with the light-emitting module. The first semiconductor layer is disposed over the encapsulation layer, the first light-emitting layer covers the first wavelength-conversion layer, and the second light-emitting layer covers the second wavelength-conversion layer.

The display device and the method for manufacturing thereof can be applied to various types of electronic devices. To make the features and advantages of this disclosure more apparent and readily understood, various embodiments will be described in detail below with reference to the accompanying drawings.

### BRIEF DESCRIPTION OF THE DRAWINGS

The embodiments of the present disclosure can be more fully understood by referring to the following detailed description in conjunction with the accompanying drawings. It should be noted that certain components may not be drawn to scale. For clarity, the dimensions of some components may be exaggerated or reduced.

FIG. 1A shows a top view of a wavelength-conversion module according to an embodiment.

FIG. 1B shows a cross-sectional view taken along line A-A’ in FIG. 1A.

FIG. 1C shows a cross-sectional view taken along line B-B’ in FIG. 1A.

FIG. 2A shows a top view of a light-emitting module according to an embodiment.

FIG. 2B shows a cross-sectional view taken along line C-C’ in FIG. 2A.

FIG. 3A shows a top view of a display device according to an embodiment.

FIG. 3B shows a cross-sectional view taken along line D-D’ in FIG. 3A.

FIG. 3C shows a cross-sectional view taken along line E-E’ in FIG. 3A.

FIG. 4A and FIG. 4B show top views of display devices according to multiple embodiments.

FIG. 5A and FIG. 5B show cross-sectional views of display devices according to multiple embodiments.

### DETAILED DESCRIPTION

Multiple embodiments and examples are provided to illustrate implementations of the disclosed device. Specific component examples and configurations are described to simplify and clarify the embodiments and are not limiting. For example, when a first component is said to be “on” a second component, this may include direct contact or indirect placement with one or more intervening layers. Component identifiers and/or characters may be reused across embodiments for clarity without implying relationships among different embodiments.

Terms regarding disposition and connection, such as “disposed,” “connected,” and similar terms, unless specifically defined, can refer to direct contact or indirect contact with intervening components. The terms apply to both movable and fixed structures.

Terms “first,” “second,” etc. are used for distinction and naming and do not limit quantity, order of manufacture, or assembly sequence.

The terms “approximately,” “about,” and “substantially” generally refer to within ±10%, ±5%, ±3%, ±2%, ±1%, or ±0.5% of a given value or range. Ranges stated as “between a first value and a second value” include the endpoints and values therebetween. Comparative values or directions may include tolerance; “equal” may imply within the tolerances above. “Perpendicular” may refer to angles between 80° and 100°, and “parallel” may refer to angles between 0° and 10°.

Unless otherwise defined, terms (including technical and scientific terms) have meanings commonly understood by those of ordinary skill in the art in light of the context. Dictionary definitions should be construed consistent with the relevant technology and context of the disclosure, without overly idealized or formal interpretations unless explicitly defined herein.

For clarity, some elements may be omitted in drawings. Additional elements may be included in some embodiments; elements may be substituted or omitted in others. Additional process steps may be provided before, during, and/or after formation steps; some steps may be substituted, omitted, or reordered.

In display devices, multiple semiconductor stacks are typically formed on a substrate, and electrodes are disposed on the stacks to enable light emission by applying a voltage to the electrodes. However, the height differences of these electrodes complicate subsequent manufacturing processes and reduce overall product yield. Furthermore, if the electrodes are disposed on the light-emitting surface of the semiconductor stack, the light-emitting area of the semiconductor stack emitting light outward may be insufficient even if the electrodes are placed at the four corners of these semiconductor stacks. The disclosure provides a display device including a wavelength-conversion module and a light-emitting module that are coupled together. By using a conductive structure in the wavelength-conversion module to position the electrodes on one side of three semiconductor stacks, the problem of insufficient light-emitting area can be effectively solved. Furthermore, by forming multiple electrodes of equal height, the complexity of subsequent manufacturing processes can be reduced.

In the disclosure, the display devices 1A to 1E can be obtained by coupling a wavelength-conversion module 10 to a light-emitting module 11. In one embodiment, the manufacturing method of the display device includes: forming a wavelength-conversion module 10; forming a light-emitting module 11; and coupling the wavelength-conversion module 10 to the light-emitting module 11. To fully illustrate the technical content and advantages of this disclosure, the structures of the wavelength-conversion module 10 and the light-emitting module 11 will be described in detail below. It should be noted that the steps of forming the wavelength-conversion module 10 and forming the light-emitting module 11 can be performed sequentially, simultaneously, or in reverse order, and are not limited to the specific order described herein.

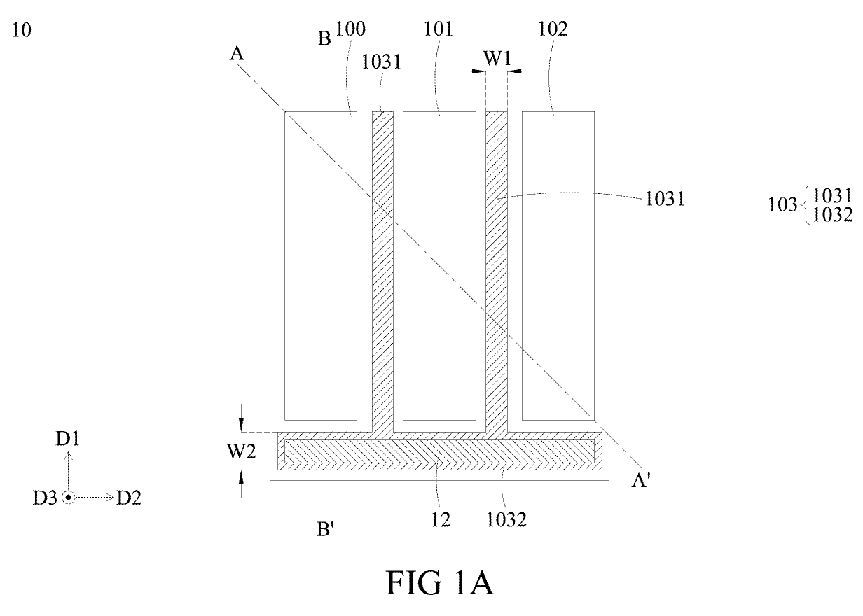

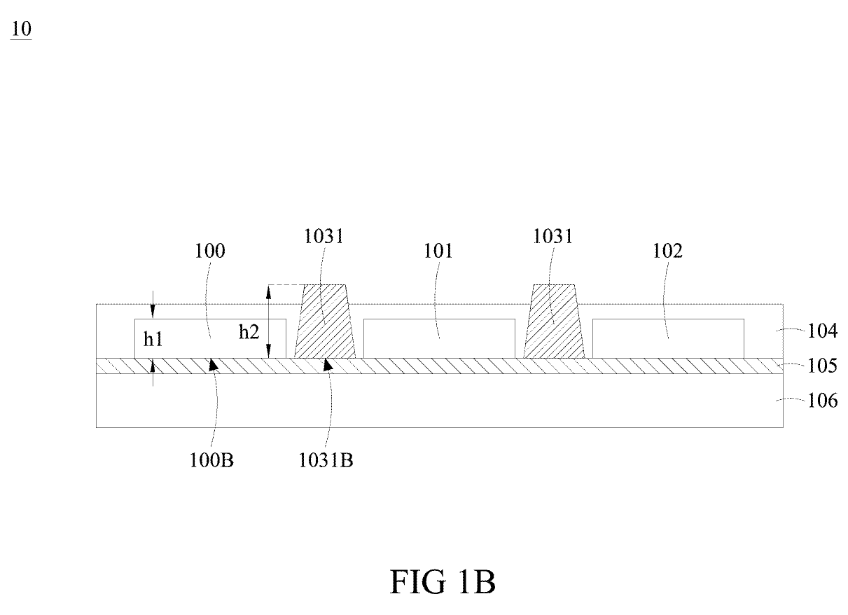

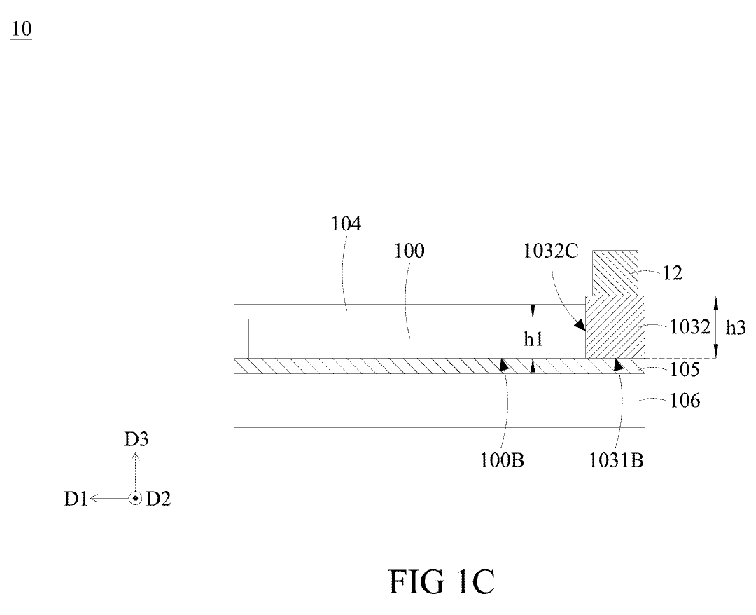

As shown in FIGS. 1A-1C, a wavelength-conversion module 10 is provided. The wavelength-conversion module 10 includes a first wavelength-conversion layer 100, a second wavelength-conversion layer 101, a third wavelength-conversion layer 102, a conductive structure 103, an encapsulation layer 104, a first light-transmitting layer 105, and a light-transmitting substrate 106. In one embodiment, before or after coupling the light-emitting module 11 to the wavelength-conversion module 10, a second electrode 12 can be disposed on a second portion 1032 of the conductive structure 103 in the wavelength-conversion module 10 (see below for details).

As shown in FIGS. 1A and 1B, the first wavelength-conversion layer 100, the second wavelength-conversion layer 101, and the third wavelength-conversion layer 102 are arranged side by side and are located on the same elevation. These wavelength-conversion layers are used to convert the light emitted by the light-emitting module 11 into different color lights. For example, the first wavelength-conversion layer 100, the second wavelength-conversion layer 101, and the third wavelength-conversion layer 102 convert excitation light (e.g., ultraviolet light) into red light, green light, and blue light, respectively. That is, the first wavelength-conversion layer 100, the second wavelength-conversion layer 101, and the third wavelength-conversion layer 102 form three primary color lights, which can be used as a pixel. In another embodiment, the first wavelength-conversion layer 100, the second wavelength-conversion layer 101, and the third wavelength-conversion layer 102 can form other color combinations. In another embodiment, the light-emitting module 11 emits blue light, and the first wavelength-conversion layer 100 and the second wavelength-conversion layer 101 convert the blue light into green light or red light, respectively. The third wavelength-conversion layer 102 is used as a light-transmitting layer, allowing the blue light emitted by the light-emitting module 11 to pass through the third wavelength-conversion layer 102.

In one embodiment, the first wavelength-conversion layer 100, the second wavelength-conversion layer 101, and the third wavelength-conversion layer 102 include phosphors, quantum dots (QDs), or combinations thereof. In one embodiment, one or more of the first wavelength-conversion layer 100, the second wavelength-conversion layer 101, and the third wavelength-conversion layer 102 include green phosphors to convert ultraviolet or blue light emitted by the light-emitting module 11 into green light.

In one embodiment, any two of the first wavelength-conversion layer 100, the second wavelength-conversion layer 101, and the third wavelength-conversion layer 102 have equal dimensions. For example, the first wavelength-conversion layer 100 and the second wavelength-conversion layer 101 have the same length, width, or height. In other embodiments, these wavelength-conversion layers have different dimensions to adjust the emission regions for different color lights. In one embodiment, the spacings between adjacent layers of the first wavelength-conversion layer 100, the second wavelength-conversion layer 101, and the third wavelength-conversion layer 102 are the same. In other embodiments, the spacings between adjacent wavelength-conversion layers are different.

As shown in FIGS. 1A-1C, the conductive structure 103 has a first portion 1031 and a second portion 1032 that are connected to each other. The first portion 1031 is disposed between the first wavelength-conversion layer 100 and the second wavelength-conversion layer 101, and also between the second wavelength-conversion layer 101 and the third wavelength-conversion layer 102. The second portion 1032 is disposed on one side of the first wavelength-conversion layer 100, the second wavelength-conversion layer 101, and the third wavelength-conversion layer 102. The first portion 1031 of the conductive structure 103 is electrically connected to the light-emitting module 11, and the second portion 1032 is electrically connected to the second electrode 12 (see below for details).

As shown in FIG. 1A, in one embodiment, the first portion 1031 extends along a first direction D1, and the second portion 1032 extends along a second direction D2, wherein the first direction D1 is perpendicular to the second direction D2. In one embodiment, the first direction D1 and the second direction D2 are intersected with each other by an angle between 70 degrees and 110 degrees. In one embodiment, the first portion 1031 has a first width W1 along the second direction D2, and the second portion 1032 has a second width W2 along the first direction D1, wherein the first width W1 is smaller than the second width W2.

As shown in FIG. 1B, in one embodiment, the lower surface of the first portion 1031 is coplanar with the lower surfaces of the wavelength-conversion layers (including the first wavelength-conversion layer 100, the second wavelength-conversion layer 101, and the third wavelength-conversion layer 102). For example, the first wavelength-conversion layer 100 has a first lower surface 100B, and the first portion 1031 has a second lower surface 1031B coplanar with the first lower surface 100B. Similarly, the lower surfaces of the second wavelength-conversion layer 101 and the third wavelength-conversion layer 102 are also coplanar with the second lower surface 1031B of the first portion 1031. In one embodiment, the heights of the wavelength-conversion layers (including the first wavelength-conversion layer 100, the second wavelength-conversion layer 101, and the third wavelength-conversion layer 102) are less than the height of the first portion 1031. For example, the first wavelength-conversion layer 100 has a first height h1, and the first portion 1031 has a second height h2, and the first height h1 is less than the second height h2. In other words, the upper surface of the first portion 1031 is higher than the upper surface of the first wavelength-conversion layer 100.

As shown in FIG. 1C, in one embodiment, the lower surface of the second portion 1032 is coplanar with the lower surfaces of the wavelength-conversion layers. For example, the second portion 1032 has a third lower surface 1032B, and the first lower surface 100B is coplanar with the third lower surface 1032B. Similarly, the lower surfaces of the second wavelength-conversion layer 101 and the third wavelength-conversion layer 102 are also coplanar with the third lower surface 1032B of the second portion 1032. In one embodiment, the heights of the wavelength-conversion layers are smaller than the height of the second portion 1032. For example, the second portion 1032 has a third height h3, and the first height h1 is less than the third height h3. In other words, the upper surface of the second portion 1032 is higher than the upper surface of the first wavelength-conversion layer 100.

As shown in FIG. 1B, in one embodiment, the width of the first portion 1031 upwardly decreases. In one embodiment, the first portion 1031 has a trapezoidal profile. In other embodiments, the first portion 1031 has a rectangular or polygonal profile. As shown in FIG. 1C, in one embodiment, the width of the second portion 1032 remains constant. In one embodiment, the second portion 1032 has a rectangular profile. In other embodiments, the second portion 1032 has a trapezoidal or polygonal profile.

In one embodiment, the first portion 1031 and the second portion 1032 include metals, metal compounds, other suitable conductive materials, or combinations thereof. Metals include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), or alloys thereof. Metal compounds include tantalum nitride (TaN), titanium nitride (TiN), tungsten silicide (WSi₂), indium tin oxide (ITO), indium oxide (InOₓ), tin oxide (SnOₓ), cadmium tin oxide (CTO), antimony tin oxide (ATO), aluminum-doped zinc oxide (AZO), zinc tin oxide (ZTO), gallium zinc oxide (GZO), indium tungsten oxide (IWO), zinc oxide (ZnO), indium zinc oxide (IZO), or indium gallium zinc oxide (IGZO).

As shown in FIGS. 1A-1C, the encapsulation layer 104 at least partially covers the first portion 1031, the first wavelength-conversion layer 100, the second wavelength-conversion layer 101, and the third wavelength-conversion layer 102. In one embodiment, the encapsulation layer 104 protects the wavelength-conversion layers from physical damage or contamination. The height of the first portion 1031 is greater than the thickness of the encapsulation layer 104, so that the first portion 1031 protrudes from the encapsulation layer 104, enabling the first portion 1031 to be electrically connected to the light-emitting module 11.

In one embodiment, the encapsulation layer 104 further separates the wavelength-conversion layers from directly connecting to the first portion 1031. For example, the first portion 1031 is separated from the first wavelength-conversion layer 100 through the encapsulation layer 104, the first portion 1031 is separated from the second wavelength-conversion layer 101 through the encapsulation layer 104, and the first portion 1031 is separated from the third wavelength-conversion layer 102 through the encapsulation layer 104. As shown in FIG. 1C, in one embodiment, the encapsulation layer 104 also covers the sidewall 1032C of the second portion 1032, and the encapsulation layer 104 is in direct contact with the second portion 1032. The second portion 1032 is also separated from any wavelength-conversion layer through the encapsulation layer 104. In other embodiments, there is a gap between the encapsulation layer 104 and the second portion 1032 to avoid direct contact between the encapsulation layer 104 and the second portion 1032.

In one embodiment, the encapsulation layer 104 includes a light-transmitting material. The encapsulation layer 104 has a transmittance at least 90% for visible and/or ultraviolet light. For example, the transmittance of the encapsulation layer 104 to visible or ultraviolet light is 90%, 92%, 94%, 96%, 98%, 99%, or any value or range between the above values. In some embodiments, the material of the encapsulation layer 104 includes polyimide (PI), polycarbonate (PC), polyethylene terephthalate (PET), polypropylene (PP), other suitable materials, or combinations thereof.

As shown in FIGS. 1B and 1C, the first light-transmitting layer 105 is disposed below the wavelength-conversion layers and the first portion 1031, and contacts the first lower surface 100B and the second lower surface 1031B. In one embodiment, the first light-transmitting layer 105 is used to enhance the electrical connection between the first portion 1031 and the second portion 1032. In some cases, the contact interface between the first portion 1031 and the second portion 1032 may be too small, resulting in excessively high resistance between them, or even electrical connection failure. Therefore, the first light-transmitting layer 105 is used to electrically connect the first portion 1031 and the second portion 1032, thereby enhancing the electrical connection between them. It should be noted that if the contact interface between the first portion 1031 and the second portion 1032 is large, the first light-transmitting layer 105 can be omitted.

In one embodiment, the first light-transmitting layer 105 includes a transparent conductive material. For example, the first light-transmitting layer 105 has a transmittance at least 90% for visible and/or ultraviolet light, but the disclosure is not limited thereto. For example, the transmittance of the first light-transmitting layer 105 to visible or ultraviolet light is 90%, 92%, 94%, 96%, 98%, 99%, or any value or range between the above values. In one embodiment, the transparent conductive material includes tantalum nitride (TaN), titanium nitride (TiN), tungsten silicide (WSi₂), indium tin oxide (ITO), indium oxide (InOₓ), tin oxide (SnOₓ), cadmium tin oxide (CTO), antimony tin oxide (ATO), aluminum-doped zinc oxide (AZO), zinc tin oxide (ZTO), gallium zinc oxide (GZO), indium tungsten oxide (IWO), zinc oxide (ZnO), indium zinc oxide (IZO), or indium gallium zinc oxide (IGZO), etc.

As shown in FIGS. 1B and 1C, the light-transmitting substrate 106 is disposed below the first light-transmitting layer 105. In one embodiment, the light-transmitting substrate 106 supports components thereon, such as the first light-transmitting layer 105, the first wavelength-conversion layer 100, the second wavelength-conversion layer 101, the third wavelength-conversion layer 102, the conductive structure 103, and the encapsulation layer 104. In one embodiment, the light-transmitting substrate 106 includes a light-transmitting material. For example, the light-transmitting substrate 106 has a transmittance at least 90% for visible and/or ultraviolet light. For example, the transmittance of the light-transmitting substrate 106 to visible or ultraviolet light is 90%, 92%, 94%, 96%, 98%, 99%, or any value or range between the above values. In one embodiment, the light-transmitting substrate 106 includes glass, quartz, sapphire, ceramic, or a combination thereof.

As shown in FIG. 1B, in one embodiment, the second electrode 12 is disposed on the second portion 1032 of the conductive structure 103, and is electrically connected to the first semiconductor layer 110 of the light-emitting module 11 through the conductive structure 103 in subsequent processes. In one embodiment, the second electrode 12 serves as a cathode of the display device 1A to supply electrical energy to one or more light-emitting units. In another embodiment, the second electrode 12 serves as an anode of the display device 1A. As shown in FIG. 1C, in one embodiment, the width of the second electrode 12 along the first direction D1 is smaller than the width of the second portion 1032 along the first direction D1. In one embodiment, the second electrode 12 is made of a metal, a metal compound, other suitable conductive materials, or a combination thereof. Refer to the foregoing description for further details of each component.

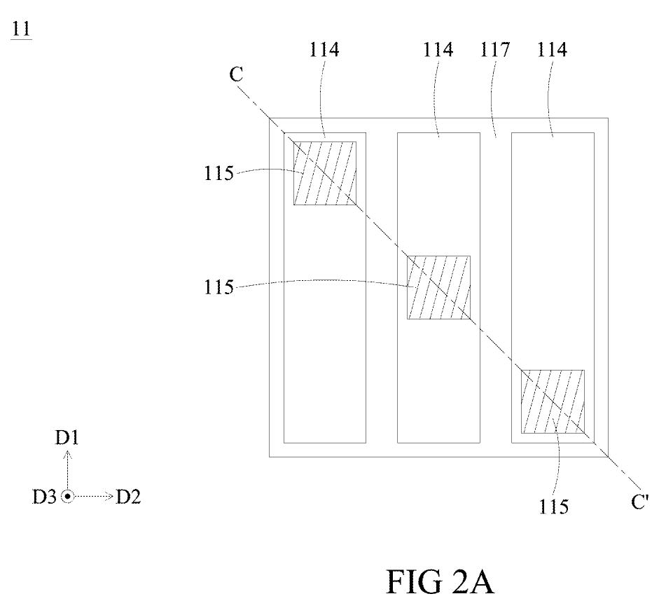

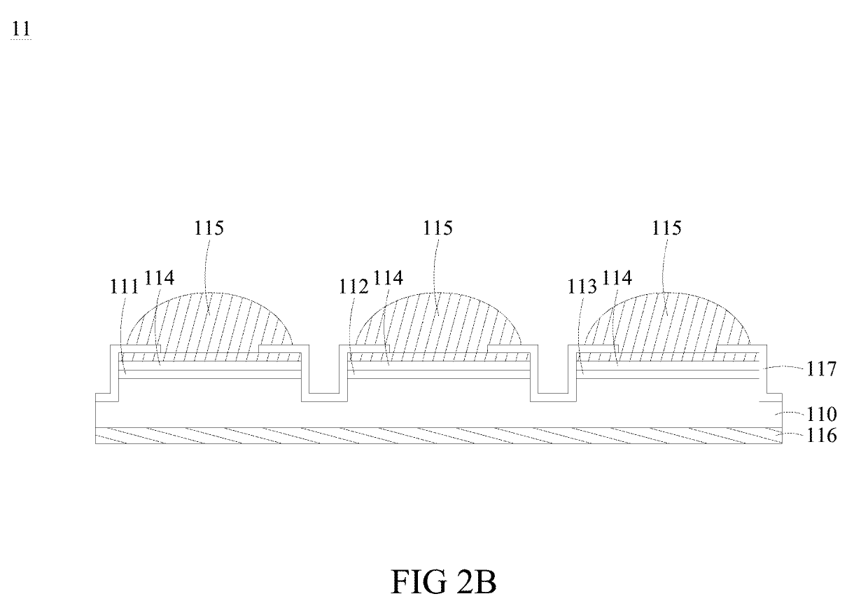

FIG. 2A shows a top view of a light-emitting module 11 according to an embodiment of the present disclosure, and FIG. 2B shows a cross-sectional view taken along line C-C’ in FIG. 2A. As shown in FIGS. 2A and 2B, the light-emitting module 11 includes a first semiconductor layer 110, a first light-emitting layer 111, a second light-emitting layer 112, a third light-emitting layer 113, a plurality of second semiconductor layers 114, and a second light-transmitting layer 116. In one embodiment, multiple first electrodes 115 are disposed on the respective second semiconductor layer 114 of the light-emitting module 11 before or after connecting the light-emitting module 11 to the wavelength-conversion module 10.

As shown in FIG. 2B, the first light-emitting layer 111, the second light-emitting layer 112, and the third light-emitting layer 113 are disposed on the first semiconductor layer 110 and are disposed between the first semiconductor layer 110 and the second semiconductor layer 114. Each of the first light-emitting layer 111, the second light-emitting layer 112, and the third light-emitting layer 113, combined with the first semiconductor layer 110 and the second semiconductor layer 114, constitute a light-emitting unit. Each light-emitting unit is used to emit light, such as ultraviolet light or blue light. In one embodiment, the color of the light emitted by the first light-emitting layer 111, the second light-emitting layer 112, and the third light-emitting layer 113 depends on their material composition. In one embodiment, the first light-emitting layer 111, the second light-emitting layer 112, and the third light-emitting layer 113 comprise InGaN-based materials and emit blue to deep-blue light with peak wavelengths between 400 and 490 nanometers. In another embodiment, the first light-emitting layer 111, the second light-emitting layer 112, and the third light-emitting layer 113 comprise AlGaN-based materials and emit ultraviolet light with peak wavelengths between 250 and 400 nanometers.

In one embodiment, the first semiconductor layer 110, the first light-emitting layer 111, the second light-emitting layer 112, the third light-emitting layer 113, and the second semiconductor layer 114 contain group II-VI materials or group III-V materials. For example, the group II-VI materials include zinc selenide (ZnSe), and the group III-V materials include gallium nitride (GaN), aluminum nitride (AlN), indium nitride (InN), indium gallium nitride (InGaN), aluminum gallium nitride (AlGaN), aluminum indium gallium nitride (AlInGaN), or combinations thereof.

In one embodiment, a doping process is performed on the first semiconductor layer 110 and the second semiconductor layer 114 so that the first semiconductor layer 110 contains a first dopant to have a first conductivity type, and the second semiconductor layer 114 contains a second dopant to have a second conductivity type which is different from the first conductivity type. For example, the doping process includes in-situ doping during epitaxial growth, ion implantation after epitaxial growth, other suitable doping processes, or combinations thereof. In one embodiment, the first conductivity type is p-type, used to provide holes, and the second conductivity type is n-type, used to provide electrons. Alternatively, the first conductivity type is n-type, used to provide electrons, and the second conductivity type is p-type, used to provide holes. In one embodiment, the first or second dopant includes magnesium (Mg), zinc (Zn), silicon (Si), carbon (C), or tellurium (Te).

As shown in FIG. 2B, multiple first electrodes 115 are disposed on different second semiconductor layers 114 and are each electrically connected to their respective underlying second semiconductor layers 114. In one embodiment, the first electrodes 115 of the display device 1A serve as anodes to supply electrical energy to the light-emitting unit. In another embodiment, the first electrodes 115 serve as cathodes in the display device 1A.

In one embodiment, as shown in FIG. 2A, the first electrode 115 has a rectangular profile. In other embodiments, the first electrode 115 has a circular, elliptical, triangular, polygonal, or other suitable shape. In one embodiment, as shown in FIG. 2A, the plurality of first electrodes 115 do not overlap each other in the horizontal direction (e.g., the second direction D2) to avoid short circuits caused by two adjacent first electrodes 115 coming into contact with each other due to overflow during the forming process. In another embodiment, the plurality of first electrodes 115 partially or completely overlap in the horizontal direction (e.g., the second direction D2). In one embodiment, as shown in FIG. 2B, the first electrode 115 has an arcuate profile. For example, the width of the first electrode 115 upwardly decreases.

As shown in FIG. 2B, the second light-transmitting layer 116 is disposed below and electrically connected to the first semiconductor layer 110. In one embodiment, the second light-transmitting layer 116 is used to electrically connect the first semiconductor layer 110 to the first portion 1031 of the conductive structure 103 of the wavelength-conversion module 10, so as to improve the stability of the electrical connection between the first portion 1031 and the first semiconductor layer 110.

In one embodiment, the second light-transmitting layer 116 includes a light-transmitting material. For example, the second light-transmitting layer 116 has a transmittance at least 90% for visible and/or ultraviolet light. For example, the transmittance of the second light-transmitting layer 116 to visible or ultraviolet light is 90%, 92%, 94%, 96%, 98%, 99%, or any value or range between the above values. In one embodiment, the light-transmitting material includes tantalum nitride (TaN), titanium nitride (TiN), tungsten silicide (WSi₂), indium tin oxide (ITO), indium oxide (InOₓ), tin oxide (SnOₓ), cadmium tin oxide (CTO), antimony tin oxide (ATO), aluminum-doped zinc oxide (AZO), zinc tin oxide (ZTO), gallium zinc oxide (GZO), indium tungsten oxide (IWO), zinc oxide (ZnO), indium zinc oxide (IZO), or indium gallium zinc oxide (IGZO), etc.

As shown in FIG. 2B, in one embodiment, the light-emitting module 11 further includes an insulating layer 117 covering the first semiconductor layer 110, the first light-emitting layer 111, the second light-emitting layer 112, the third light-emitting layer 113, and the second semiconductor layer 114, and exposing a portion of the second semiconductor layer 114. The first electrode 115 contacts the second semiconductor layer 114 through the exposed portion. In one embodiment, the insulating layer 117 is used to protect the semiconductor stack from accidental electrical connections between the semiconductor stack and other components, and to prevent the semiconductor stack from being damaged or contaminated by impurities.

In one embodiment, insulating layer 117 includes a dielectric material. The dielectric material includes oxide, nitride, polymer, other suitable dielectric material, or combinations thereof, such as silicon dioxide (SiO₂), silicon nitride (SiN), or aluminum oxide (Al₂O₃). In one embodiment, the insulating layer 117 further includes a distributed Bragg reflector (DBR). The distributed Bragg reflector can include multiple optical stacked layers. By controlling the thicknesses, materials, and optical properties of the optical stacked layers, constructive or destructive interference of light can be achieved.

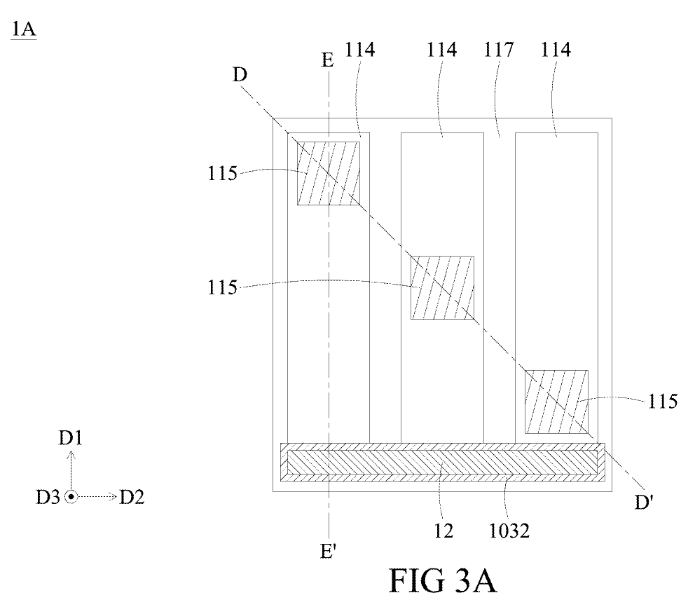

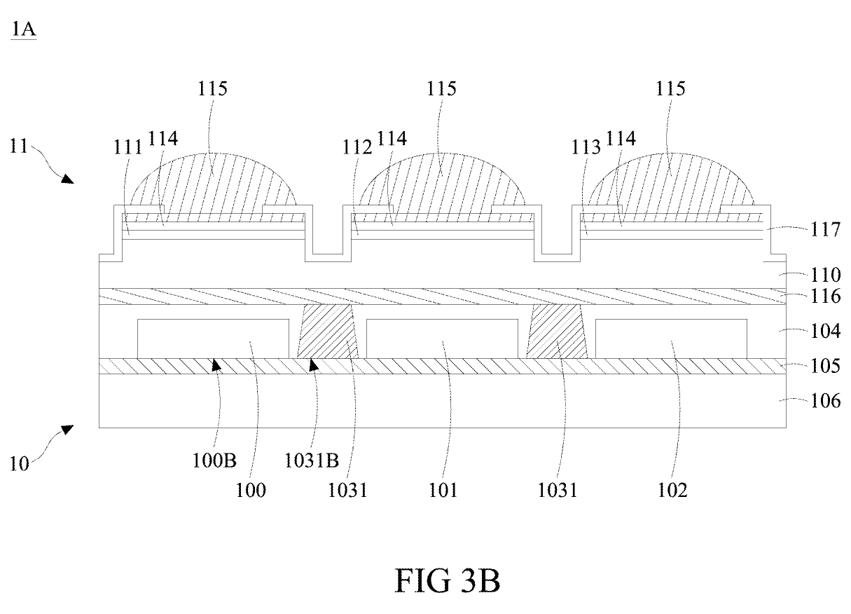

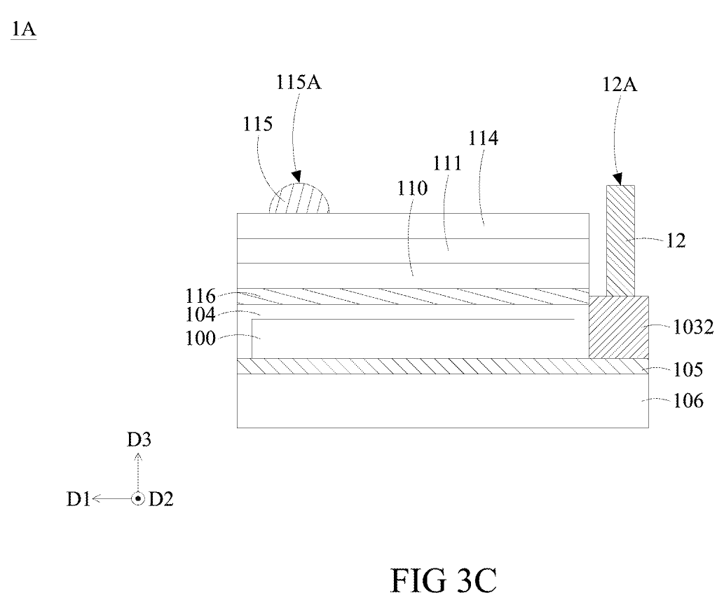

As shown in FIGS. 3A to 3C, a wavelength-conversion module 10 and a light-emitting module 11 are combined to form a display device 1A. In one embodiment, the second light-transmitting layer 116 of the light-emitting module 11 faces the encapsulation layer 104 of the wavelength-conversion module 10, and the light-emitting module 11 is attached to the wavelength-conversion module 10. The first semiconductor layer 110 is disposed on the encapsulation layer 104, and the first, second, and third wavelength-conversion layers 100, 101, 102 are disposed between the light-transmitting substrate 106 and the light-emitting module 11.

The display device 1A includes the wavelength-conversion module 10 and the light-emitting module 11. The wavelength-conversion module 10 includes a first wavelength-conversion layer 100, a second wavelength-conversion layer 101, and a conductive structure 103. The first wavelength-conversion layer 100 has a first lower surface 100B. The conductive structure 103 has a first portion 1031 and a second portion 1032 which are connected to each other, and the first portion 1031 is disposed between the first wavelength-conversion layer 100 and the second wavelength-conversion layer 101. The first portion 1031 has a second lower surface 1031B, and the second lower surface 1031B is coplanar with the first lower surface 100B. The light-emitting module 11 is disposed over the wavelength-conversion module 10 with the second portion 1032 exposed. The light-emitting module 11 includes a first semiconductor layer 110, a first light-emitting layer 111, and a second light-emitting layer 112. The first light-emitting layer 111 and the second light-emitting layer 112 are disposed on the first semiconductor layer 110, and respectively overlap the first wavelength-conversion layer 100 and the second wavelength-conversion layer 101 in a plan view. For detailed information on each component, please refer to the preceding content.

As shown in FIG. 3B, in one embodiment, the first wavelength-conversion layer 100, the second wavelength-conversion layer 101, and the third wavelength-conversion layer 102 are all separated from the light-emitting module 11 through the encapsulation layer 104. In other words, the first wavelength-conversion layer 100, the second wavelength-conversion layer 101, and the third wavelength-conversion layer 102 do not directly contact the second light-transmitting layer 116 of the light-emitting module 11. In one embodiment, after connecting the wavelength-conversion module 10 and the light-emitting module 11, the first wavelength-conversion layer 100 and the first portion 1031 are still separated by the encapsulation layer 104, the second wavelength-conversion layer 101 and the first portion 1031 are still separated by the encapsulation layer 104, and the third wavelength-conversion layer 102 and the first portion 1031 are still separated by the encapsulation layer 104.

As shown in FIG. 3B, in one embodiment, a second light-transmitting layer 116 is disposed between the first semiconductor layer 110 and the first portion 1031, and the first portion 1031 of the conductive structure 103 is electrically connected to the first semiconductor layer 110 through the second light-transmitting layer 116. In one embodiment, the first portion 1031 does not directly contact the first semiconductor layer 110, but is electrically connected to the first semiconductor layer 110 through the second light-transmitting layer 116.

As shown in FIG. 3C, in one embodiment, the first electrode 115 has a first upper surface 115A, the second electrode 12 has a second upper surface 12A, and the height difference between the first upper surface 115A and the second upper surface 12A is less than 5 µm. For example, the height difference between the first upper surface 115A and the second upper surface 12A is 4.5 µm, 4.0 µm, 3.5 µm, 3.0 µm, 2.5 µm, 2.0 µm, 1.5 µm, 1.0 µm, 0.5 µm, 0.1 µm, or any value or range between the above values. In one embodiment, the first upper surface 115A and the second upper surface 12A are coplanar to facilitate subsequent processing. In addition, since the second electrode 12 is disposed on one side of the three light-emitting units, it occupies only a small portion of the overall area; consequently, the configuration effectively addresses the issue of insufficient light-emitting area in the display device. In one embodiment, the first electrode 115 has a rectangular or trapezoidal profile (not shown), and the height difference between its first upper surface 115A and the second upper surface 12A is less than 5 µm. In another embodiment, the second upper surface 12A of the second electrode 12 is a curved surface (not shown), and the height difference between the first upper surface 115A and the second upper surface 12A is less than 5 µm.

As mentioned above, the present disclosure provides a display device 1A in which a wavelength-conversion module 10 and a light-emitting module 11 are separately fabricated and subsequently bonded together, thereby effectively addressing certain issues in the prior art. Further aspects are described below with reference to some embodiments.

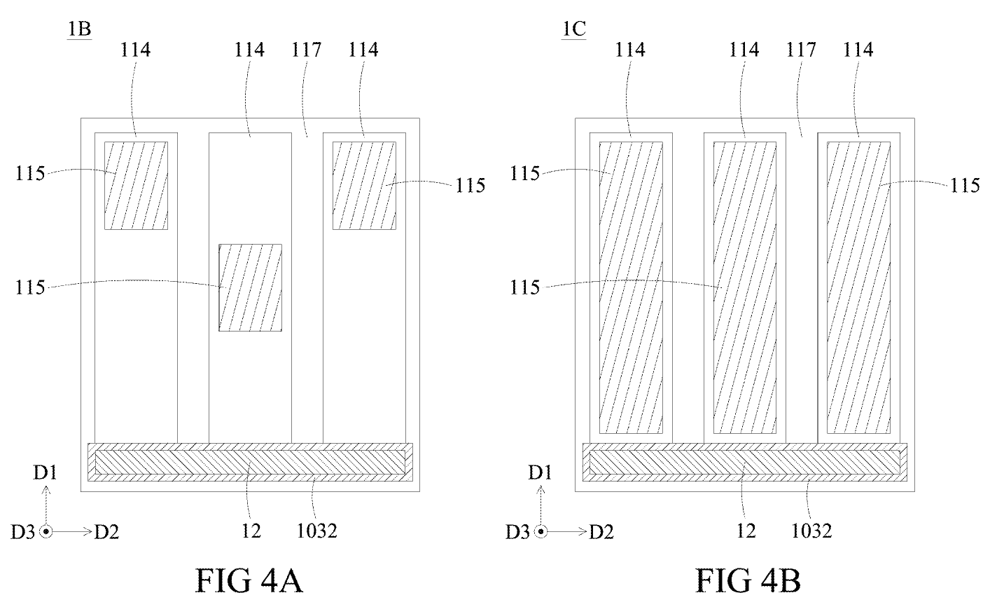

As shown in FIG. 4A, in one embodiment, in a top view, the plurality of first electrodes 115 of the display device 1B partially overlap in the horizontal direction (e.g., the second direction D2). For example, adjacent first electrodes 115 do not overlap in that direction, whereas non-adjacent first electrodes 115 partially overlap, thereby providing greater design flexibility for the display device 1B.

As shown in FIG. 4B, in one embodiment, in a top view, the plurality of first electrodes 115 of the display device 1C completely overlap in the horizontal direction (e.g., the second direction D2). For example, all the first electrodes 115 overlap each other in the horizontal direction (e.g., the second direction D2) to give the display device 1C greater design flexibility. It should be noted that a material with low flowability can be selected to form the first electrodes 115 to avoid the first electrodes 115 forming unintended electrical connections with other components due to overflow.

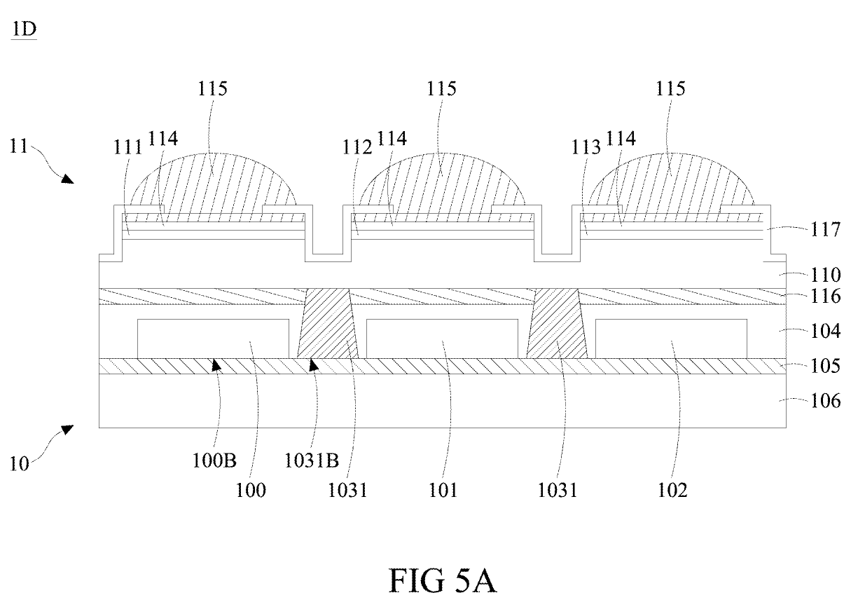

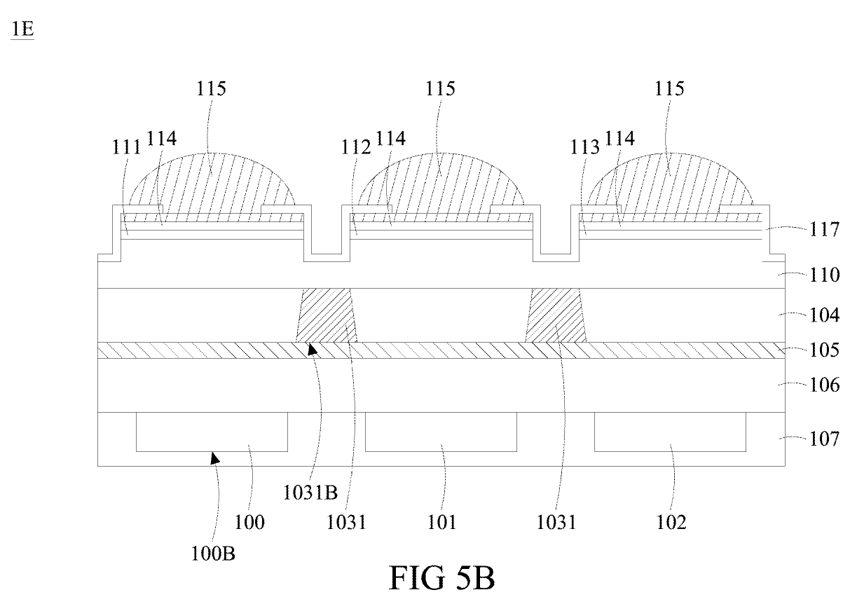

As shown in FIG. 5A, in one embodiment, a first portion 1031 of the conductive structure 103 in the display device 1D penetrates through the second light-transmitting layer 116 to directly contact and electrically connect to the first semiconductor layer 110. The configuration increases the contact area between the conductive structure 103 and the first semiconductor layer 110, thereby enhancing the reliability of the electrical connection.

As shown in FIG. 5B, in one embodiment, the wavelength-conversion layers and the conductive structure 103 in the display device 1E are disposed at different elevations. The first wavelength-conversion layer 100, the second wavelength-conversion layer 101, and the third wavelength-conversion layer 102 are disposed in the encapsulation layer 107 rather than in the encapsulation layer 104. The encapsulation layer 107 is disposed on the opposite side of the light-transmitting substrate 106 from the encapsulation layer 104. Accordingly, the first lower surface 100B of the first wavelength-conversion layer 100, the lower surface 101B of the second wavelength-conversion layer 101, and the lower surface 102B of the third wavelength-conversion layer 102 are not coplanar with the second lower surface 1031B of the first portion 1031. The arrangement enhances the design flexibility of the display device 1E.

In one embodiment, the encapsulation layer 107 includes a light-transmitting material. The encapsulation layer 107 has a transmittance at least 90% for visible and/or ultraviolet light. For example, the transmittance of the encapsulation layer 107 to visible or ultraviolet light is 90%, 92%, 94%, 96%, 98%, 99%, or any value or range between the above values. In one embodiment, the material of the encapsulation layer 107 includes polyimide (PI), polycarbonate (PC), polyethylene terephthalate (PET), polypropylene (PP), other suitable materials, or combinations thereof. The material of the encapsulation layer 107 can be the same as or different from the material of the encapsulation layer 104.

In one embodiment, the second light-transmitting layer 116 can be omitted, allowing the first portion 1031 to directly contact the first semiconductor layer 110, thereby enhancing the design flexibility of the display device 1E.

As mentioned above, the disclosure provides a display device including a wavelength-conversion module and a light-emitting module coupled together. By utilizing a conductive structure in the wavelength-conversion module to place electrodes on one side of three semiconductor stacks, the problem of insufficient light-emitting area is effectively reduced. Furthermore, by placing the electrodes at substantially the same height, the problem of increased difficulty in subsequent manufacturing processes is also reduced.

Components in the embodiments of this disclosure can be freely combined and matched as long as they do not violate the spirit of this disclosure or conflict with it. Furthermore, the scope of protection of this disclosure is not limited to the processes, machines, manufacturing methods, material compositions, apparatuses, methods, and steps described in the specific embodiments of the specification. Any processes, machines, manufacturing methods, material compositions, apparatuses, methods, and steps currently under development or to be developed can be understood from the content of this disclosure and can be used according to this disclosure as long as they can perform substantially the same function or obtain substantially the same results as the embodiments described herein. Therefore, the scope of protection of this disclosure includes the above-described processes, machines, manufacturing methods, material compositions, apparatuses, methods, and steps. No embodiment or claim of this disclosure is required to achieve all the objects, advantages, and/or features disclosed herein.

Several embodiments have been outlined above to enable those skilled in the art to better understand the viewpoints of the disclosed embodiments. Those skilled in the art should understand that other processes and structures can be designed or modified based on the disclosed embodiments to achieve the same purposes and/or advantages as the embodiments described herein. Those skilled in the art should also understand that such equivalent processes and structures do not depart from the spirit and scope of this disclosure, and various changes, substitutions, and alterations can be made without departing from the spirit and scope of this disclosure.

What is claimed is:

1. A display device, comprising:
a wavelength-conversion module, comprising:
a first wavelength-conversion layer having a first lower surface;
a second wavelength-conversion layer; and
a conductive structure having a first portion and a second portion which are connected to each other, the first portion disposed between the first wavelength-conversion layer and the second wavelength-conversion layer, and the first portion having a second lower surface coplanar with the first lower surface; and
a light-emitting module, disposed over the wavelength-conversion module and exposing the second portion, the light-emitting module comprising:
a first semiconductor layer disposed over the first portion; and
a first light-emitting layer and a second light-emitting layer disposed on the first semiconductor layer, the first light-emitting layer covering the first wavelength-conversion layer, and the second light-emitting layer covering the second wavelength-conversion layer.

2. The display device of claim 1, further comprising an encapsulation layer covering the first portion, the first wavelength-conversion layer, and the second wavelength-conversion layer.

3. The display device of claim 2, wherein the encapsulation layer separates the first portion from directly connecting to the first wavelength-conversion layer.

4. The display device of claim 2, wherein the second portion has a sidewall covered by the encapsulation layer.

5. The display device of claim 1, wherein the wavelength-conversion module further comprises a first light-transmitting layer that contacts the first lower surface.

6. The display device of claim 1, wherein the light-emitting module further comprises a second light-transmitting layer disposed between the first semiconductor layer and the first portion.

7. The display device of claim 6, wherein the first portion penetrates through the second light-transmitting layer, and is electrically connected to the first semiconductor layer.

8. The display device of claim 1, wherein the light-emitting module further comprises:
a second semiconductor layer, disposed on the first light-emitting layer; and
a first electrode, disposed on and electrically connected to the second semiconductor layer.

9. The display device of claim 8, further comprising:
a second electrode, disposed on the second portion and electrically connected to the first semiconductor layer through the conductive structure;
wherein the first electrode has a first upper surface, the second electrode has a second upper surface, and the first upper surface and the second upper surface have a height difference less than 5 µm.

10. The display device of claim 1, wherein the first portion has a width that upwardly decreases.

11. A method of manufacturing a display device, comprising:
providing a wavelength-conversion module, wherein the wavelength-conversion module comprises:
a first wavelength-conversion layer and a second wavelength-conversion layer, the first wavelength-conversion layer has a first lower surface; and
a conductive structure having a first portion and a second portion which are connected to each other, the first portion is disposed between the first wavelength-conversion layer and the second wavelength-conversion layer, and the first portion has a second lower surface coplanar with the first lower surface;
providing a light-emitting module, wherein the light-emitting module comprises:
a first semiconductor layer; and
a first light-emitting layer and a second light-emitting layer disposed on the first semiconductor layer; and
coupling the wavelength-conversion module to the light-emitting module, wherein the light-emitting module exposes the second portion, the first semiconductor layer is disposed over the first portion, the first light-emitting layer covers the first wavelength-conversion layer, and the second light-emitting layer covers the second wavelength-conversion layer.

12. The method of claim 11, further comprising forming an encapsulation layer, wherein the encapsulation layer covers the first portion, the first wavelength-conversion layer, and the second wavelength-conversion layer.

13. The method of claim 12, wherein the encapsulation layer separates the first portion from directly connecting to the first wavelength-conversion layer.

14. The method of claim 12, wherein the second portion has a sidewall covered by the encapsulation layer.

15. The method of claim 11, wherein the wavelength-conversion module comprises a first light-transmitting layer that contacts the first lower surface.

16. The method of claim 11, further comprising forming a second light-transmitting layer, wherein second light-transmitting layer is disposed between the first semiconductor layer and the first portion.

17. The method of claim 16, wherein the first portion penetrates through the second light-transmitting layer, and is electrically connected to the first semiconductor layer.

18. The method of claim 11, wherein the light-emitting module further comprises:
a second semiconductor layer, disposed on the first light-emitting layer; and
a first electrode, disposed on and electrically connected to the second semiconductor layer.

19. The method of claim 18, further comprising:
forming a second electrode on the second portion,
wherein the first electrode has a first upper surface, the second electrode has a second upper surface, and the first upper surface and the second upper surface have a height difference less than 5 µm after the coupling step.

20. The method of claim 11, wherein the first portion has a width that upwardly decreases.
